(19) United States
(12) Patent Application Publication
(10) Pub. No.: US 2014/0110758 A1
(43) Pub. Date: Apr. 24, 2014

(54) SEMICONDUCTOR DEVICE AND METHOD FOR PRODUCING SAME

(71) Applicants: Yu Saitoh, Itami-shi (JP); Masaya Okada, Osaka-shi (JP); Masaki Ueno, Itami-shi (JP); Makoto Kiyama, Itami-shi (JP)

(72) Inventors: Yu Saitoh, Itami-shi (JP); Masaya Okada, Osaka-shi (JP); Masaki Ueno, Itami-shi (JP); Makoto Kiyama, Itami-shi (JP)

(73) Assignee: Sumitomo Electric Industries, Ltd., Osaka-shi (JP)

(21) Appl. No.: 14/124,600

(22) PCT Filed: Jun. 8, 2011
(86) PCT No.: PCT/JP2011/063095

§ 371 Date: Dec. 6, 2013

(51) Int. Cl. H01L 29/778; H01L 29/66

(52) U.S. Cl. CPC H01L 29/7789; H01L 29/66431
USPC 257/194; 438/493

(57) ABSTRACT

The semiconductor device is formed in the form of a GaN-based stacked layer including an n-type drift layer 4, a p-type layer 6, and an n-type top layer 8. The semiconductor device includes a regrown layer 27 formed so as to cover a portion of the GaN-based stacked layer that is exposed to an opening 28, the regrown layer 27 including a channel. The channel is two-dimensional electron gas formed at an interface between the electron drift layer and the electron supply layer. When the electron drift layer 22 is assumed to have a thickness of d, the p-type layer 6 has a thickness in the range of d to 10d, and a graded p-type impurity layer 7 whose concentration decreases from a p-type impurity concentration in the p-type layer is formed so as to extend from a (p-type layer/n-type top layer) interface to the inside of the n-type top layer.

### TECHNICAL FIELD

The present invention relates to a vertical semiconductor device that is used for high power switching and has low on-resistance and excellent breakdown voltage characteristics and a method for producing the vertical semiconductor device.

### BACKGROUND ART

High reverse breakdown voltage and low on-resistance are required for high-current switching devices. Field effect transistors (FETs) that use a group III nitride-based semiconductor are excellent in terms of, for example, high breakdown voltage and high-temperature operation because of their wide band gap. Therefore, vertical transistors that use a GaN-based semiconductor have been particularly receiving attention as transistors for controlling high power. For example, PTL 1 proposes a vertical GaN-based FET whose mobility is increased and whose on-resistance is decreased by forming an opening in a GaN-based semiconductor and forming a regrown layer including a channel of two-dimensional electron gas (2DEG) at a side surface of the opening.

### CITATION LIST

### Patent Literature

PTL 1: Japanese Unexamined Patent Application Publication No. 2006-286942

### SUMMARY OF INVENTION

### Technical Problem

In the vertical FET, a p-type GaN layer that produces an effect of a guard ring is disposed in a portion around an opening in which a regrown layer is to be formed. Consequently, an npn structure is formed and therefore vertical breakdown voltage characteristics can be ensured while high mobility is achieved due to the two-dimensional electron gas that forms the channel. However, such a structure is not always a structure sufficient for achieving low on-resistance.

It is an object of the present invention to provide a semiconductor device in which low on-resistance can be stably achieved while high vertical breakdown voltage is realized and a method for producing the semiconductor device.

### Solution to Problem

A semiconductor device of the present invention is formed in the form of a GaN-based stacked layer including an n-type drift layer, a p-type layer located on the n-type drift layer, and an n-type top layer located on the p-type layer. In this semiconductor device, the GaN-based stacked layer has an opening that extends from the n-type top layer and reaches the n-type drift layer through the p-type layer. The semiconductor device includes a regrown layer located so as to cover a portion of the GaN-based stacked layer that is exposed to the opening, the regrown layer including a channel. The regrown layer includes an electron drift layer and an electron supply layer, and the channel is two-dimensional electron gas formed at an interface between the electron drift layer and the electron supply layer. When the electron drift layer is assumed to have a thickness of d, the p-type layer has a thickness in the range of d to 10d, and a graded p-type impurity layer whose concentration decreases from a p-type impurity concentration in the p-type layer is formed so as to extend from a (p-type layer/n-type top layer) interface to the inside of the n-type top layer.

According to the above structure, since the p-type layer has a thickness in the range of d to 10d, the length of the channel can be reduced while satisfactory breakdown voltage characteristics are achieved, which can decrease the on-resistance. Regarding the breakdown voltage characteristics, the graded p-type impurity layer contributes to an improvement in the breakdown voltage characteristics. Although the p-type layer alone can provide satisfactory breakdown voltage characteristics, an allowance or a safety margin for the breakdown voltage characteristics can be obtained by the presence of the graded p-type impurity layer. Furthermore, since the graded p-type impurity layer is formed so as to penetrate the n-type top layer, the graded p-type impurity layer does not directly contribute to an increase in the on-resistance or hardly affects the on-resistance. When the thickness of the p-type layer is decreased in order to decrease the on-resistance, a leakage current flowing from the n-type top layer to the n-type drift layer through the electron drift layer (normally, i-type GaN layer) is easily generated. However, since the graded p-type impurity layer penetrates the n-type top layer, the n-type top layer substantially occupies a region that has retreated away from the p-type layer or the thickness of the p-type layer substantially increases. Therefore, the generation of a leakage current flowing via the electron drift layer can be suppressed.

Regarding the thickness of the p-type layer, if the thickness of the p-type layer is less than d, satisfactory breakdown voltage characteristics cannot be achieved and the leakage current increases. On the other hand, if the thickness of the p-type layer is more than 10d, the length of the channel formed along a slope of the opening is increased to more than 10d. Consequently, the increase in the on-resistance cannot be neglected. In the present invention, the thickness of the p-type layer can be decreased, and the side effects due to the decrease in the thickness of the p-type layer can be eliminated by disposing the graded p-type impurity layer as described above. In particular cases, there are almost no side effects, and the performance improved by decreasing the thickness of the p-type layer and the performance improved by forming the graded p-type impurity layer can be provided.

It is assumed that the graded p-type impurity layer does not penetrate at least a region of the n-type top layer close to the surface. That is, in at least a region of the n-type top layer close to the surface, the p-type impurity concentration of the graded p-type impurity layer is decreased to the background level.

The GaN-based stacked layer is obtained by performing epitaxial growth on a predetermined crystal face of GaN. The GaN base may be a GaN substrate or a GaN film on a support substrate. Alternatively, by forming a GaN layer on a GaN substrate or the like during the growth of a GaN-based stacked layer and then removing a portion having a certain thickness corresponding to the thickness of the GaN substrate or the like, only a thin GaN layer may be left as a base in the form of products. The thin GaN layer left as a base may be a conductive or nonconductive layer. A drain electrode can be disposed on the top or bottom surface of the thin GaN layer depending on the production process and the structure of products.

In the case where the GaN substrate, the support substrate, or the like is left in a product, the support substrate or the substrate may be a conductive or nonconductive substrate. When the support substrate or the substrate is a conductive substrate, the drain electrode can be disposed directly on the bottom (lower) surface or top (upper) surface of the support substrate or the substrate. When the support substrate or the substrate is a nonconductive substrate, the drain electrode can be disposed above the nonconductive substrate and on a conductive layer located on the lower layer side in the semiconductor layer.

The graded p-type impurity layer can be formed so as to extend from the (p-type layer/n-type top layer) interface to the inside of the n-type top layer and have a thickness in the range of 0.5d to 3.5d. This contributes to an improvement in the breakdown voltage characteristics and suppressing of the generation of a leakage current. In addition, almost no influence is exerted on the on-resistance. If the thickness of the graded p-type impurity layer is less than 0.5d, there are only limited effects of improving the breakdown voltage characteristics and suppressing the generation of a leakage current. If the thickness of the graded p-type impurity layer is more than 3.5d, the on-resistance is adversely affected.

A p-type impurity concentration gradient in the graded p-type impurity layer can be in the range of 30 nm/decade to 300 nm/decade. If the concentration gradient of the p-type impurity is less than 30 nm/decade, the concentration gradient becomes steep like the concentration gradient at an interface. As a result, only a local effect is provided in a thin region and it is difficult to improve the breakdown voltage characteristics and suppress the generation of a leakage current. On the other hand, a concentration gradient of the p-type impurity of more than 300 nm/decade is not significantly different from an increase in the thickness of the p-type layer, which increases the risk of increasing the on-resistance.

Note that concentration gradient, measured in units of “nm/decade”, is the thickness required to decrease the impurity concentration by one decimal place.

The thickness d of the electron drift layer can be in the range of 20 nm to 400 nm. This readily provides effects such as suppressing of the generation of a leakage current due to the arrangement of the p-type layer and graded p-type impurity layer. If the thickness of the electron drift layer is less than 20 nm, the on-resistance increases because Mg diffuses into the electron drift layer from the p-type layer. If the thickness is more than 400 nm, a leakage current flowing from the n-type top layer to the n-type drift layer through the electron drift layer is easily generated.

An n-type impurity concentration of the n-type top layer can be in the range of −25% to +25% relative to the p-type impurity concentration of the p-type layer. Thus, the n-type impurity concentration of the n-type top layer is substantially equal to the p-type impurity concentration of the p-type layer. In a region from the interface to the inside of the n-type top layer, the graded p-type impurity layer includes a layer portion having almost no carriers due to the cancel out between the impurities. As a result, the breakdown voltage characteristics can be improved and also the generation of a leakage current can be suppressed.

A method for producing a semiconductor device of the present invention uses a GaN-based stacked layer. This production method includes a step of forming an n-type drift layer, a p-type layer located on the n-type drift layer, and an n-type top layer located on the p-type layer, a step of forming an opening that extends from the n-type top layer and reaches the n-type drift layer through the p-type layer, and a step of forming an electron drift layer and an electron supply layer in the opening. In the step of forming the p-type layer, when the electron drift layer is assumed to have a thickness of d, the p-type layer has a thickness in the range of d to 10d. In the step of forming the p-type layer and the n-type top layer, a graded p-type impurity layer whose concentration decreases from a p-type impurity concentration in the p-type layer is formed so as to extend from a (p-type layer/n-type top layer) interface to the inside of the n-type top layer.

According to the above method, the on-resistance can be decreased by decreasing the thickness of the p-type layer and at the same time the graded p-type impurity layer can be easily formed in the n-type top layer by introducing a p-type impurity in the p-type layer into the n-type top layer during the formation of the n-type top layer. As a result, a semiconductor device having low on-resistance and excellent breakdown voltage characteristics and low-leakage-current characteristics can be easily provided.

In the step of forming the p-type layer and the n-type top layer, the graded p-type impurity layer can be formed so as to extend from the (p-type layer/n-type top layer) interface to the inside of the n-type top layer and have a thickness in the range of 0.5d to 3.5d by performing doping such that an n-type impurity concentration of the n-type top layer is adjusted to be in the range of −25% to +25% relative to the p-type impurity concentration of the p-type layer. This can provide a semiconductor device having excellent breakdown voltage characteristics and low-leakage-current characteristics.

In the step of forming the n-type top layer, doping is performed such that the graded p-type impurity layer is formed or the n-type top layer is grown at a growth temperature in the range of 1030° C. to 1100° C. such that a p-type impurity in the p-type layer diffuses into the n-type top layer. Thus, a semiconductor device including a GaN-based semiconductor layer with the graded p-type impurity layer can be easily produced using a generally used facility and growth method.

### Advantageous Effects of Invention

According to the present invention, a semiconductor device in which low on-resistance can be stably achieved while high vertical breakdown voltage is realized can be provided.

### BRIEF DESCRIPTION OF DRAWINGS

FIG. 1 is a sectional view taken along line I-I of FIG. 3 and shows a vertical GaN-based FET according to an embodiment of the present invention.

FIG. 2A is an enlarged view at the side surface of an opening in the semiconductor device of FIG. 1.

FIG. 2B is a diagram showing the distribution of a p-type impurity in a graded p-type impurity layer in a thickness direction.

FIG. 3 is a plan view of a chip in which the semiconductor device of FIG. 1 is formed.

FIG. 4A is a diagram showing a method for producing the vertical GaN-based FET of FIG. 1, the diagram showing the state in which an epitaxial stacked layer including the graded p-type impurity layer has been formed on a GaN substrate.

FIG. 4B is a diagram showing a method for producing the vertical GaN-based FET of FIG. 1, the diagram showing the state in which an opening has been formed.

FIG. 4C is a diagram showing a method for producing the vertical GaN-based FET of FIG. 1, the diagram showing the state in which a regrown layer has been grown in the opening.

FIG. 5A is a diagram showing the state in which, at the stage of forming an opening by RIE, a resist pattern has been formed.

FIG. 5B is a diagram showing the state in which, at the stage of forming an opening by RIE, the stacked layer is etched down by performing ion irradiation.

FIG. 6 is a diagram showing a temperature-time pattern in the growth of the regrown layer.

FIG. 7A is a diagram showing the state in which an insulating layer has been grown on the regrown layer.

FIG. 7B is a diagram showing the state in which a source electrode, a drain electrode, and a gate electrode have been formed.

FIG. 8 is a diagram showing the concentration distribution of the graded p-type impurity layer in the thickness direction in a semiconductor device produced in Examples.

### DESCRIPTION OF EMBODIMENTS

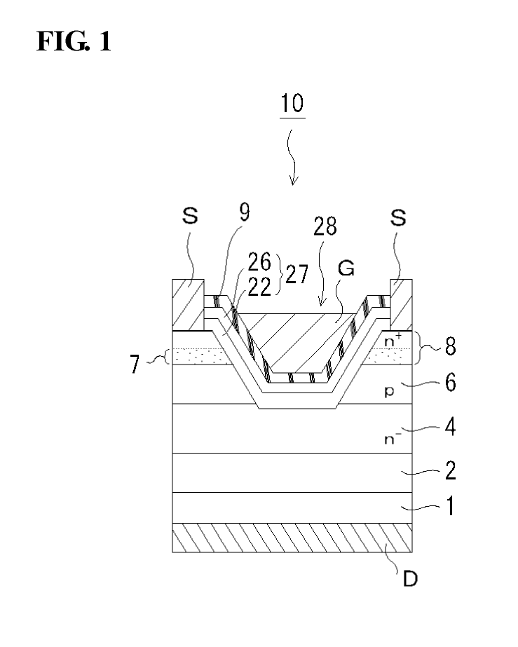

FIG. 1 is a sectional view showing a semiconductor device 10 according to an embodiment of the present invention. In this semiconductor device 10, an opening 28 is formed so as to extend from a surface of a GaN-based semiconductor layer constituted by (GaN-based substrate 1/buffer layer 2/n⁻-type drift layer 4/p-type barrier layer 6/n⁺-type contact layer 8) and reach the n⁻-type drift layer 4. The n⁺-type contact layer 8 is an alternative name given to an n-type top layer 8 and is used when the arrangement of an electrode is emphasized. When a top layer of a stacked layer is emphasized, the n⁺-type contact layer 8 is also referred to as an n⁺-type cap layer. The p-type barrier layer 6 is an alternative name given to a p-type layer 6 and is used to emphasize a barrier layer against electrons. The n⁻-type drift layer 4 serves as an n-type drift layer 4.

A regrown layer 27 including an electron drift layer 22 and an electron supply layer 26 is formed so as to cover a portion of the GaN-based semiconductor layer, the portion being exposed to the opening 28. A gate electrode G is formed above the regrown layer 27 with an insulating layer 9 disposed therebetween. A source electrode S is formed on the GaN-based semiconductor layer so as to be in contact with the electron drift layer 22 and the electron supply layer 26. A drain electrode D is disposed so as to face the source electrode S, with the n⁻-type drift layer 4 and the like sandwiched therebetween. Two-dimensional electron gas (2DEG) is formed at an interface between the electron drift layer 22 and the electron supply layer 26. The 2DEG constitutes a channel of a vertical electric current flowing between the source electrode and the drain electrode.

The features of the semiconductor device 10 according to this embodiment are that (1) when the electron drift layer 22 is assumed to have a thickness of d, the p-type barrier layer 6 has a thickness in the range of d to 10d and (2) a graded p-type impurity layer 7 whose concentration decreases from the p-type impurity concentration in the p-type barrier layer 6 is formed so as to extend from a (p-type barrier layer 6/n⁺-type contact layer 8) interface to the inside of the n⁺-type contact layer 8.

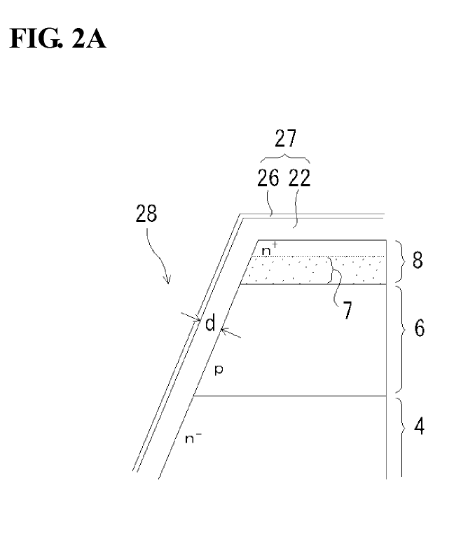

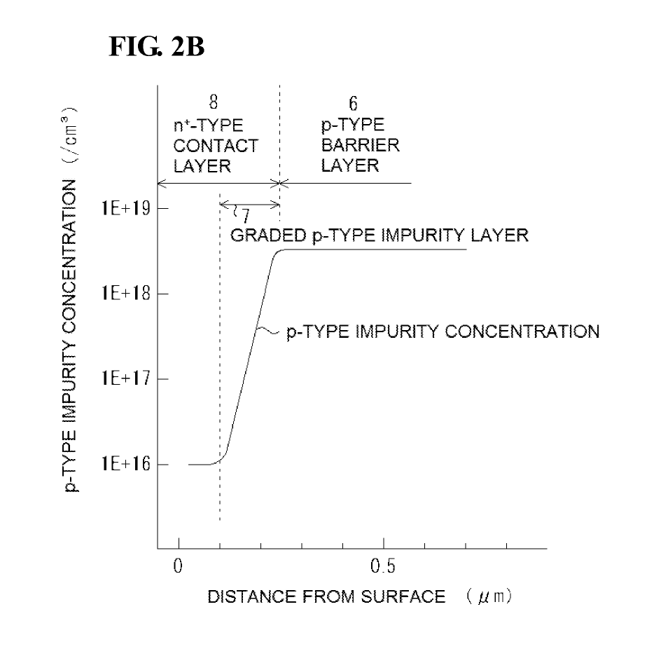

FIG. 2A is an enlarged sectional view showing the regrown layer 27 and (n⁻-type drift layer 4/p-type barrier layer 6/n⁺-type contact layer 8) at the side surface of the opening 28 in the semiconductor device 10 shown in FIG. 1. FIG. 2B is a diagram showing the distribution of a p-type impurity concentration in a thickness direction. In FIG. 2A, the thickness of the electron drift layer 22 is represented by d. As described above, when the electron drift layer 22 is assumed to have a thickness of d, the p-type barrier layer 6 may have a thickness in the range of d to 10d. The graded p-type impurity layer 7 may have a thickness in the range of 0.5d to 3.5d.

Focusing on the type of main p-type impurity such as Mg that makes the p-type barrier layer 6 function as a p-type layer, as shown in FIG. 2B, the thickness of the graded p-type impurity layer 7 is defined as the thickness from the (p-type barrier layer 6/n⁺-type contact layer 8) interface to a portion having a background concentration of Mg in the n⁺-type contact layer 8. For example, the Mg concentration at the (p-type barrier layer 6/n⁺-type contact layer 8) interface is equal to the Mg concentration in the p-type barrier layer 6, which is about 5×10¹⁸ (5E+18) (cm⁻³). The background concentration of Mg in the n⁺-type contact layer 8 is, for example, about 1×10¹⁶ (1E+16) (cm⁻³). The thickness between the (p-type barrier layer 6/n⁺-type contact layer 8) interface and the face (point) at which the Mg concentration of the graded p-type impurity layer 7 intersects the background concentration of Mg in the n⁺-type contact layer 8 corresponds to the thickness of the graded p-type impurity layer 7.

By arranging the thin p-type barrier layer 6 and the graded p-type impurity layer 7, the following effects can be provided.

(E1) Since the p-type barrier layer 6 has a thickness in the range of d to 10d, the length of a channel can be reduced to 10d or less while satisfactory breakdown voltage characteristics are achieved, which can decrease the on-resistance.

(E2) The presence of the graded p-type impurity layer 7 can improve the breakdown voltage characteristics compared with the case where the p-type barrier layer 6 alone is disposed. Although the p-type layer alone can provide satisfactory breakdown voltage characteristics, an allowance or a safety margin for the breakdown voltage characteristics can be obtained by the presence of the graded p-type impurity layer 7. Furthermore, since the graded p-type impurity layer 7 is formed so as to penetrate the n-type top layer, the graded p-type impurity layer 7 does not directly contribute to an increase in the on-resistance or hardly affects the on-resistance.

(E3) In particular, when the thickness of the p-type barrier layer 6 is decreased in order to decrease the on-resistance, a leakage current flowing from the n⁺-type contact layer 8 to the n⁻-type drift layer 4 through the electron drift layer (normally, i-type GaN layer) 22 is easily generated. However, since the graded p-type impurity layer 7 penetrates the n⁺-type contact layer 8, the n⁺-type contact layer 8 substantially occupies a region that has retreated away from the p-type barrier layer 6 (thin shape formed by the retreat toward the surface) or the thickness of the p-type barrier layer 6 substantially increases. Therefore, the generation of a leakage current flowing via the electron drift layer 22 can be suppressed. The graded p-type impurity layer 7 serves as a resistance to such a leakage current path.

In summary, a decrease in the thickness of the p-type layer (E1) decreases the on-resistance and at the same time the graded p-type impurity layer 7 (E2) improves the breakdown voltage characteristics and (E3) suppresses the generation of a leakage current.

It is assumed that the graded p-type impurity layer 7 does not penetrate at least a region of the n⁺-type contact layer 8 close to the surface. That is, in at least a region of the n⁺-type contact layer 8 close to the surface, the p-type impurity concentration of the graded p-type impurity layer 7 is decreased to the background level (e.g., 1×10¹⁶ cm⁻³).

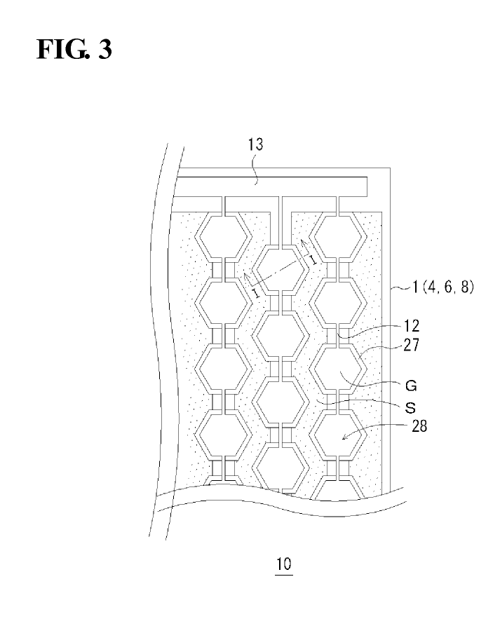

FIG. 3 is a plan view of a chip in which the semiconductor device is formed and shows which part of the chip the sectional view of FIG. 1 corresponds to. As shown in FIG. 3, the opening 28 and the gate electrode G have a hexagonal shape and a region around the opening 28 and gate electrode G is substantially covered with the source electrode S while the source electrode S does not overlap a gate wiring line 12. Consequently, a closest-packed structure (honey-comb structure) is formed and thus the gate electrode has a long perimeter per unit area, that is, the on-resistance can be decreased. An electric current flows through a path of source electrode S→channel in the regrown layer 27→n⁻-type drift layer 4→drain electrode D. The gate electrode G, the gate wiring line 12, and a gate pad 13 constitute a gate structure. In order to prevent the source electrode S and the wiring line thereof from interfering with the gate structure, the source wiring line is disposed on an interlayer-insulating layer (not shown). A via hole is formed in the interlayer-insulating layer, and the source electrode S including a conductive plug is conductively connected to a source conductive layer (not shown) on the interlayer-insulating layer. As a result, a source structure including the source electrode S can have low electrical resistance and high mobility, which are suitable for high-power devices.

The perimeter of the opening per unit area can also be increased by densely arranging elongated openings instead of employing the hexagonal honey-comb structure. Consequently, the current density can be improved.

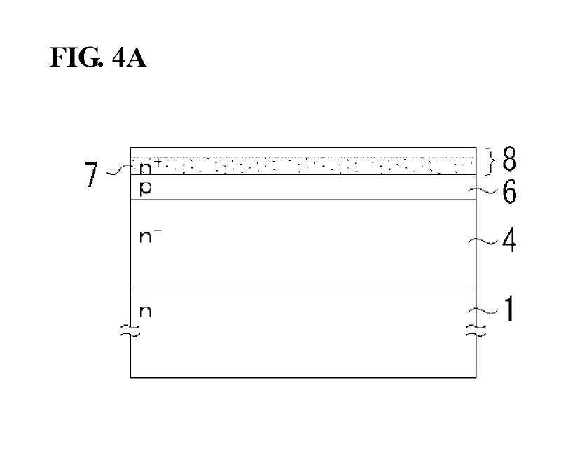

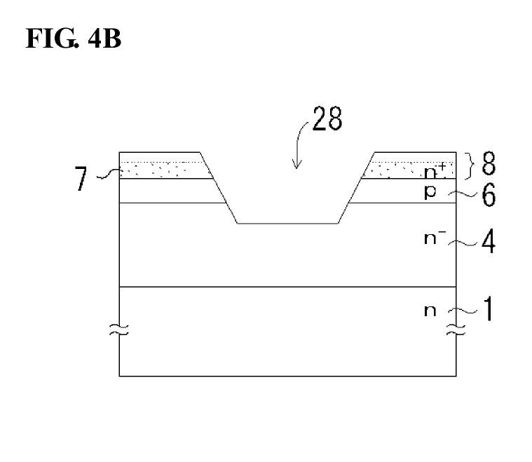

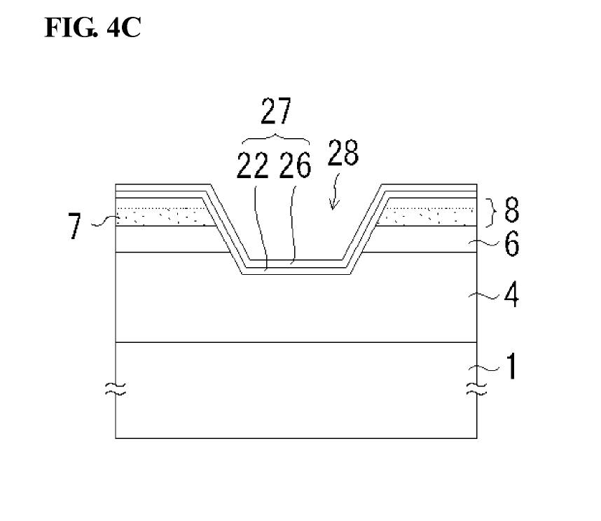

A method for producing the semiconductor device 10 according to this embodiment will now be described. As shown in FIG. 4A, a GaN-based stacked layer including n⁻-type GaN drift layer 4/p-type GaN layer 6/n⁺-type GaN contact layer 8 is epitaxially grown on a GaN substrate 1 corresponding to the above-described GaN substrate. A GaN-based buffer layer may be inserted between the GaN substrate 1 and the n⁻-type GaN drift layer 4.

The formation of the above layers is performed by, for example, metal-organic chemical vapor deposition (MOCVD). Instead of the MOCVD, molecular beam epitaxy (MBE) may be employed. Thus, a GaN-based semiconductor layer having good crystallinity can be formed. In the case where the GaN substrate 1 is formed by growing a gallium nitride film on a conductive substrate using MOCVD, trimethylgallium is used as a gallium raw material. High-purity ammonia is used as a nitrogen raw material. Purified hydrogen is used as a carrier gas. The purity of the high-purity ammonia is 99.999% or more and the purity of the purified hydrogen is 99.999995% or more. A hydrogen-based silane is used as a Si raw material for an n-type dopant and cyclopentadienyl magnesium is used as a Mg raw material for a p-type dopant. A conductive GaN substrate having a diameter of two inches is used as the substrate. The substrate is cleaned at 1030° C. at 100 Torr in an atmosphere of ammonia and hydrogen. Subsequently, the temperature of the substrate is increased to 1050° C. and a gallium nitride layer is grown at 200 Torr at a V/III ratio of 1500, which is the ratio of the nitrogen raw material and gallium raw material.

The n⁻-type GaN layer 4/p-type GaN layer 6/n⁺-type GaN layer 8 are grown on the GaN substrate 1 in that order. A method for forming the graded p-type impurity layer 7 that extends from the (p-type GaN layer 6/n⁺-type GaN layer 8) interface to the inside of the n⁺-type GaN layer 8 is described below.

(S1) When the growth of the p-type GaN layer 6 is switched to the growth of the n⁺-type GaN layer 8, the initial temperature in the growth of the n⁺-type GaN layer 8 is increased to facilitate the diffusion of a p-type impurity such as Mg from the p-type GaN layer 6 to the n⁺-type GaN layer 8.

(S2) In the growth of the n⁺-type GaN layer 8, the amount of a p-type dopant introduced, such as cyclopentadienyl magnesium serving as a raw material of Mg, is adjusted to be equal to that in the case of the p-type barrier layer 6 for an initial short time of the growth of the n⁺-type GaN layer 8 and is then decreased in a gradient manner.

The concentration gradient of the p-type impurity of the graded p-type impurity layer 7 may be 30 nm/decade to 300 nm/decade. A concentration gradient of the p-type impurity of more than 300 nm/decade is not significantly different from an increase in the thickness of the p-type layer, which increases the risk of increasing the on-resistance. A concentration gradient of less than 30 nm/decade provides only a local effect in a thin region, and it is difficult to improve the breakdown voltage characteristics and suppress the generation of a leakage current.

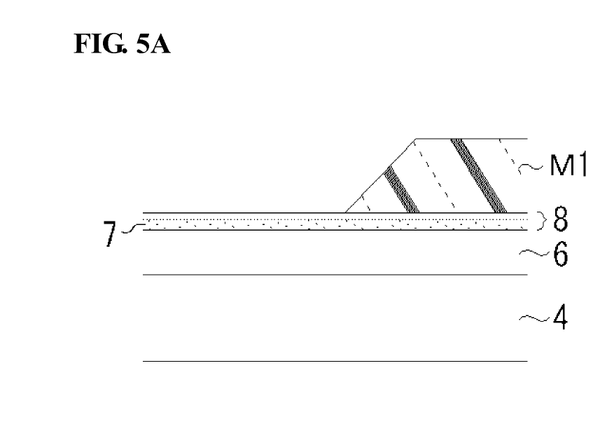

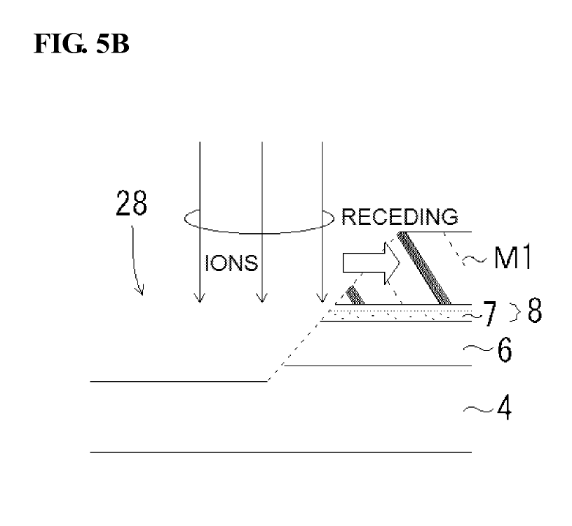

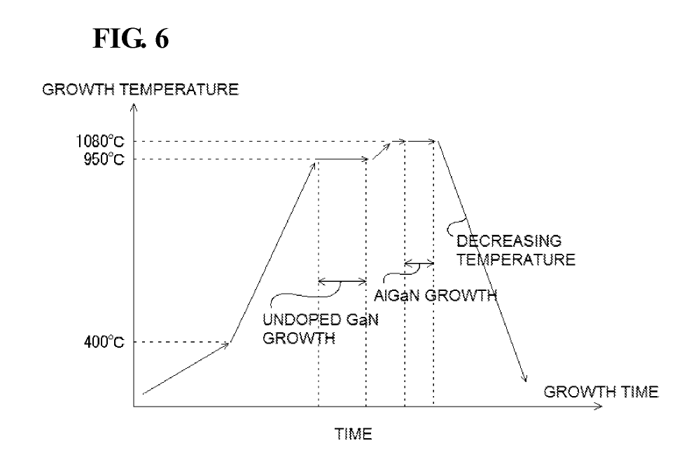

As shown in FIG. 4B, an opening 28 is formed by etching. In this etching of the opening 28, as shown in FIGS. 5A and 5B, a resist pattern Ml is formed on the top of epitaxial layers 4, 6, and 8, and the resist pattern Ml is then etched by reactive ion etching (RIE) to cause the resist pattern Ml to recede, whereby an opening 28 is formed. Subsequently, the resist pattern Ml is removed and the wafer is cleaned. The wafer is inserted into an MOCVD apparatus and a regrown layer 27 including an electron drift layer 22 composed of undoped GaN and an electron supply layer 26 composed of undoped AlGaN is grown as shown in FIG. 4C. In the growth of the undoped GaN layer 22 and undoped AlGaN layer 26, thermal cleaning is performed in an atmosphere of (NH₃+H₂), and then an organic metal material is supplied while (NH₃+H₂) is being introduced. FIG. 6 shows a temperature-time pattern in the growth of the GaN layer 22 and AlGaN layer 26.

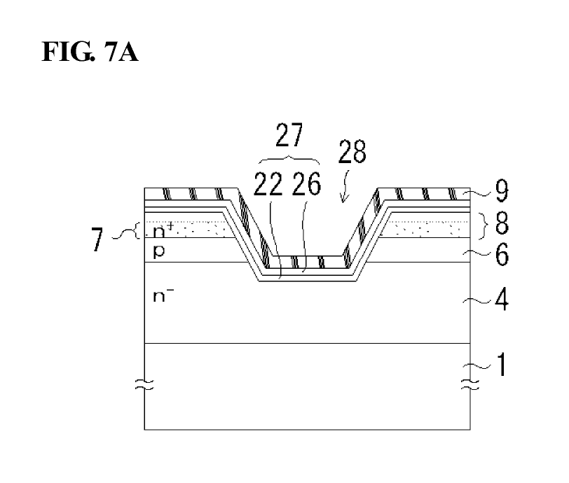

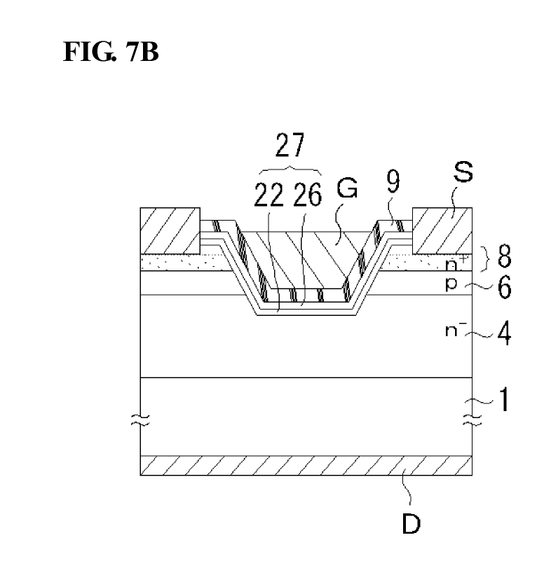

Subsequently, the wafer is taken out of the MOCVD apparatus. An insulating layer 9 is grown as shown in FIG. 7A. A source electrode S and a drain electrode D are formed on the top surface of the epitaxial layer and the bottom surface of the GaN-based substrate 1, respectively, by photolithography and ion beam deposition as shown in FIG. 7B. A gate electrode G is further formed on the side surface of the opening 28.

### Examples

The semiconductor device 10 shown in FIG. 7B was produced on the basis of the production method described in the above embodiment to investigate the presence (thickness and concentration gradient) of the graded p-type impurity layer 7 formed so as to extend from the p-type barrier layer 6 to the inside of the n⁺-type contact layer 8. Members other than the graded p-type impurity layer 7 in the semiconductor device 10 are as follows. Mg was used as a p-type impurity of the p-type GaN barrier layer 6. The graded p-type impurity layer 7 was formed on the basis of the above method (S1). That is, at the beginning of the formation of the n⁺-type cap layer 8, the temperature was increased to 1050° C. to facilitate the diffusion of Mg into the n⁺-type cap layer 8.

n⁻-type GaN drift layer 4: thickness 5 μm, Si concentration 1×10¹⁶ (1E16) cm⁻³
p-type GaN barrier layer 6: thickness 0.5 μm, Mg concentration 1×10¹⁸ (1E18) cm⁻³
n⁺-type GaN contact layer 8: thickness 0.2 μm, Si concentration 1×10¹⁸ (1E18) cm⁻³
Electron drift layer (undoped GaN) 22: thickness 0.1 μm
Electron supply layer (undoped AlGaN layer) 26: thickness 0.02 μm, Al content 25%

Referring FIG. 6, the undoped GaN layer 22 was grown at 950° C. for a growth time of about 240 seconds so as to have a thickness of 0.1 μm. The undoped AlGaN layer 26 was grown at 1080° C. for a growth time of about 100 seconds so as to have a thickness of 0.02 μm. After the undoped AlGaN layer 26 was grown, the supply of an organic metal material was stopped and the temperature was decreased in a nitrogen atmosphere.

Subsequently, the semiconductor device 10 serving as a test specimen was etched in the depth direction from the surface of the n⁺-type cap layer 8, and at the same time the concentration distribution of Mg in the depth direction was measured by secondary ion-microprobe mass spectrometry (SIMS).

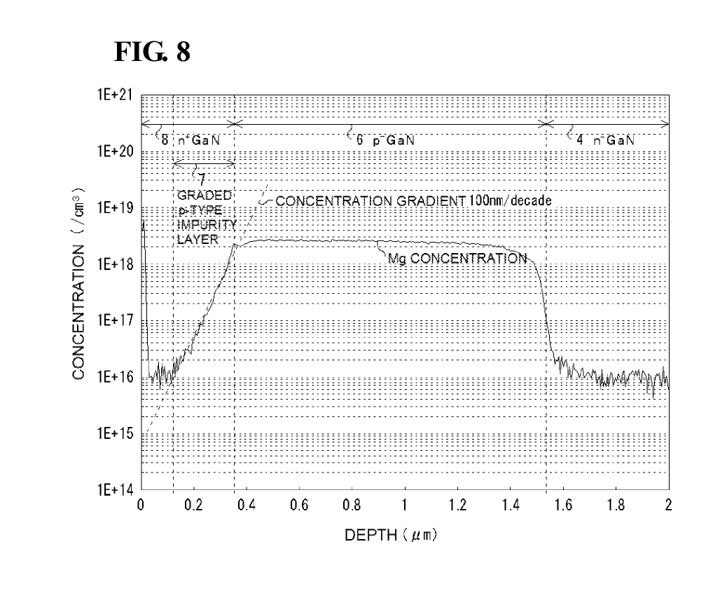

FIG. 8 is a diagram showing the concentration distribution of Mg in the depth direction, the concentration distribution being measured by SIMS. The graded p-type impurity layer (graded Mg-impurity layer) 7 is formed with a thickness of 0.22 μm. Since the electron drift layer 22 has a thickness of 0.1 μm (=d), the graded p-type impurity layer 7 has a thickness of 2.2d. The p-type barrier layer 6 has a thickness of 0.5 μm, which is a thickness of 5d. By forming the p-type layer 6 whose thickness is decreased and the graded p-type impurity layer (graded Mg-impurity layer) 7, as described above, (E1) the on-resistance can be decreased, (E2) the breakdown voltage characteristics can be improved, and (E3) the generation of a leakage current can be suppressed.

The structures disclosed in the above embodiments of the present invention are mere examples and the scope of the present invention is not limited to these embodiments. The scope of the present invention is defined by the appended claims, and all changes that fall within the scope of the claims and the equivalence thereof are therefore embraced by the claims.

### INDUSTRIAL APPLICABILITY

According to the present invention, a semiconductor device in which low on-resistance can be stably achieved while high vertical breakdown voltage is realized can be provided. Therefore, a high current can be controlled substantially without a loss.

### REFERENCE SIGNS LIST

1 GaN substrate
2 buffer layer
4 n⁻-type GaN drift layer
6 p-type GaN layer
7 graded p-type impurity layer
8 n⁺-type GaN top layer
9 insulating layer
10 vertical GaN FET
12 gate wiring line
13 gate pad
22 GaN electron drift layer
26 AlGaN electron supply layer
27 regrown layer
28 opening
Ml resist pattern
D drain electrode
G gate electrode
S source electrode

1. A semiconductor device formed in the form of a GaN-based stacked layer including an n-type drift layer, a p-type layer located on the n-type drift layer, and an n-type top layer located on the p-type layer,
the GaN-based stacked layer having an opening that extends from the n-type top layer and reaches the n-type drift layer through the p-type layer, the semiconductor device comprising:
a regrown layer located so as to cover a portion of the GaN-based stacked layer that is exposed to the opening, the regrown layer including a channel,
wherein the regrown layer includes an electron drift layer and an electron supply layer, and the channel is two-dimensional electron gas formed at an interface between the electron drift layer and the electron supply layer, and
when the electron drift layer is assumed to have a thickness of d, the p-type layer has a thickness in the range of d to 10d, and a graded p-type impurity layer whose concentration decreases from a p-type impurity concentration in the p-type layer is formed so as to extend from a (p-type layer/n-type top layer) interface to the inside of the n-type top layer.

2. The semiconductor device according to claim 1, wherein the graded p-type impurity layer is formed so as to extend from the (p-type layer/n-type top layer) interface to the inside of the n-type top layer and have a thickness in the range of 0.5d to 3.5d.

3. The semiconductor device according to claim 1, wherein a p-type impurity concentration gradient in the graded p-type impurity layer is in the range of 30 nm/decade to 300 nm/decade.

4. The semiconductor device according to claim 1, wherein the thickness d of the electron drift layer is in the range of 20 nm to 400 nm.

5. The semiconductor device according to claim 1, wherein an n-type impurity concentration of the n-type top layer is in the range of −25% to +25% relative to the p-type impurity concentration of the p-type layer.

6. A method for producing a semiconductor device that uses a GaN-based stacked layer, the method comprising:
a step of forming an n-type drift layer, a p-type layer located on the n-type drift layer, and an n-type top layer located on the p-type layer;
a step of forming an opening that extends from the n-type top layer and reaches the n-type drift layer through the p-type layer; and
a step of forming an electron drift layer and an electron supply layer in the opening,
wherein, in the step of forming the p-type layer, when the electron drift layer is assumed to have a thickness of d, the p-type layer has a thickness in the range of d to 10d, and
in the step of forming the n-type top layer, a graded p-type impurity layer whose concentration decreases from a p-type impurity concentration in the p-type layer is formed so as to extend from a (p-type layer/n-type top layer) interface to the inside of the n-type top layer.

7. The method for producing a semiconductor device according to claim 6, wherein, in the step of forming the n-type top layer, the graded p-type impurity layer is formed so as to extend from the (p-type layer/n-type top layer) interface to the inside of the n-type top layer and have a thickness in the range of 0.5d to 3.5d by performing doping such that an n-type impurity concentration of the n-type top layer is adjusted to be in the range of −25% to +25% relative to the p-type impurity concentration of the p-type layer.

8. The method for producing a semiconductor device according to claim 6, wherein, in the step of forming the n-type top layer, doping is performed such that the graded p-type impurity layer is formed or the n-type top layer is grown at a growth temperature in the range of 1030° C. to 1100° C. such that a p-type impurity in the p-type layer diffuses into the n-type top layer.
